(19) United States
(12) Patent Application Publication
(10) Pub. No.: US 2024/0213083 A1
(43) Pub. Date: Jun. 27, 2024

(54) SEMICONDUCTOR DEVICE AND MANUFACTURING METHOD THEREOF

(71) Applicant: HON HAI PRECISION INDUSTRY CO., LTD., New Taipei City (TW)

(72) Inventor: Yun-Hung SHEN, Hsinchu City (TW)

(21) Appl. No.: 18/164,553

(22) Filed: Feb. 3, 2023

(30) Foreign Application Priority Data
Dec. 26, 2022 (TW) 111149961

(51) Int. Cl. H01L 21/762; H01L 29/66; H01L 29/78

(52) U.S. Cl. CPC H01L 21/76232; H01L 29/66621; H01L 29/66636; H01L 29/7848

(57) ABSTRACT

A semiconductor device includes a substrate, a plurality of epitaxial structures and a plurality of gate structures. The substrate includes a plurality of recesses and a plurality of convex portions. Each of the convex portions is located between the two adjacent recesses. The epitaxial structures are located in the recesses of the substrate respectively. Each of the epitaxial structures includes a first transition layer, a second transition layer and an epitaxial layer. The first transition layer is located on a bottom surface and a sidewall of one of the recesses. The second transition layer is disposed along the first transition layer, in which a material of the second transition layer is different from a material of the first transition layer. The epitaxial layer is located on the second transition layer and fills one of the recesses. The gate structures are located on the convex portions of the substrate respectively.

### RELATED APPLICATIONS

This application claims priority to Taiwan Application Serial Number 111149961, filed Dec. 26, 2022, which is herein incorporated by reference.

### BACKGROUND

### Field of Disclosure

The present disclosure relates to a semiconductor device and a manufacturing method of the semiconductor device.

### Description of Related Art

In the operation of a transistor, the compressive strain exerted to the current channel by the source/drain region formed by epitaxial structure is crucial. However, internal energy accumulated between the lattices is sometimes too large due to the difference between the lattice constant of the epitaxial structure and the lattice constant of the silicon substrate below, which results in the difficulty of maintaining the local equilibrium. As a result, the epitaxial structure will release the internal energy through a misfit dislocation defect.

However, when the internal energy is released, it means the compressive strain exerted to the current channel by the source/drain region formed by epitaxial structure is decreased, which results in the decrease of the charge mobility in the channel, which affects the magnitude of the saturation current and the operation of the transistor. Besides, a misfit dislocation defect also tends to cause the generation of junction leakage.

### SUMMARY

One aspect of the present disclosure provides a semiconductor device.

According to one embodiment of the present disclosure, a semiconductor device includes a substrate, a plurality of epitaxial structures and a plurality of gate structures. The substrate includes a plurality of recesses and a plurality of convex portions. Each of the convex portions is located between the two adjacent recesses. The epitaxial structures are located in the recesses of the substrate respectively. Each of the epitaxial structures includes a first transition layer, a second transition layer and an epitaxial layer. The first transition layer is located on a bottom surface and a sidewall of one of the recesses. The second transition layer is disposed along the first transition layer, in which a material of the second transition layer is different from a material of the first transition layer. The epitaxial layer is located on the second transition layer and fills one of the recesses. The gate structures are located on the convex portions of the substrate respectively.

In some embodiments of the present disclosure, each of the epitaxial structures has a convex portion, and the convex portion protrudes to one of the convex portions of the substrate.

In some embodiments of the present disclosure, each of the sidewall of the recesses of the substrate has a concave portion, and the sidewall contacts the first transition layer.

In some embodiments of the present disclosure, the concave portions of the sidewalls of the recesses couples with the convex portions of the epitaxial structures respectively.

In some embodiments of the present disclosure, the semiconductor device further includes a shallow trench isolation (STI) located in the substrate, in which one of the epitaxial structures has a sidewall abuts against the STI, and the sidewall abuts against the STI has no convex portion.

In some embodiments of the present disclosure, a sidewall of the STI faces the sidewall abuts against the STI.

In some embodiments of the present disclosure, the sidewall of the STI has no concave portion.

In some embodiments of the present disclosure, the material of the first transition layer includes pseudomorphic silicon germanium crystal.

In some embodiments of the present disclosure, the material of the second transition layer includes silicon nucleation crystal.

In some embodiments of the present disclosure, a material of the epitaxial layer includes silicon germanium.

One aspect of the present disclosure provides a manufacturing method of a semiconductor device.

According to one embodiment of the present disclosure, a manufacturing method of a semiconductor device includes forming a shallow trench isolation (STI), a plurality of gate structures and a plurality of transition recesses on a substrate, in which the transition recesses are located between the gate structures and between the STI and the gate structure closest to the STI; etching the transition recesses to form a plurality of recesses, in which a sidewall of each of the recesses has a concave portion; forming a first transition layer on bottom surfaces and the sidewalls of the recesses; forming a second transition layer along the first transition layer, in which a material of the first transition layer is different from a material of the second transition layer; and growing an epitaxial layer on the second transition layer.

In some embodiments of the present disclosure, forming the first transition layer on the bottom surfaces and the sidewalls of the recesses includes depositing a silicon atom layer in the recesses; implanting a germanium ion to the silicon atom layer; and performing a thermal anneal to the silicon atom layer to form the first transition layer.

In some embodiments of the present disclosure, forming the second transition layer along the first transition layer includes depositing a silicon atom layer in the recesses.

In some embodiments of the present disclosure, forming the second transition layer along the first transition layer is performed by atomic layer deposition (ALD) or chemical vapor deposition (CVD).

In some embodiments of the present disclosure, forming the transition recesses is performed by dry etching, and etching the transition recesses to form the recesses is performed by wet etching.

In the aforementioned embodiments of the present disclosure, since the epitaxial structure of the semiconductor device has the first transition layer and the second transition layer, such that it won't accumulate too much internal energy between the epitaxial layer located on the second transition layer and the substrate below the first transition layer due to the big difference of the lattice constant of the substrate and the lattice constant of the epitaxial layer. The first transition layer and the second transition layer can help release the internal energy to prevent the rupture of the lattice due to the release of internal energy and causes the situation of non-alignment of the lattice. At the same time, it also prevents misfit dislocation defect, such that the compressive strain exerted to the current channel by the source/drain region formed by epitaxial structure can be preserved, and thus preserves the charge mobility of the current channel and the magnitude of the saturation current, so that the transistor can operate without the possibility of the decrease of the saturation current.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a cross-sectional view of a semiconductor device according to one embodiment of the present disclosure.

FIG. 2 is an enlarged view of the epitaxial structure of FIG. 1.

FIG. 3 to FIG. 8 are cross-sectional views at intermediate steps of a manufacturing method of the semiconductor device of FIG. 1.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the drawings. The spatially relative terms are intended to encompass different orientations of the device in use or operation in addition to the orientation depicted in the drawings. The apparatus may be otherwise oriented (rotated 90 degrees or at other orientations) and the spatially relative descriptors used herein may likewise be interpreted accordingly.

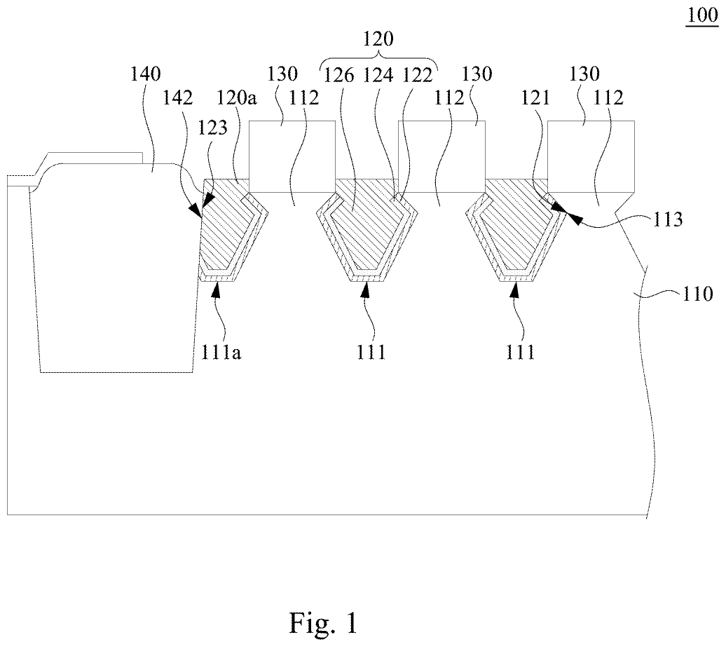

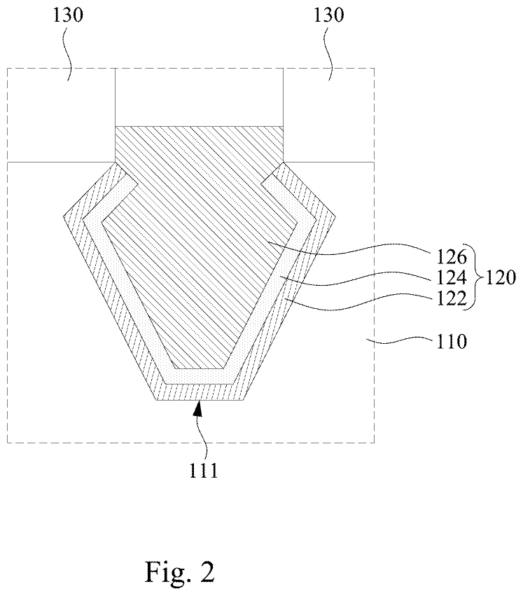

FIG. 1 is a cross-sectional view of a semiconductor device 100 according to one embodiment of the present disclosure. FIG. 2 is an enlarged view of the epitaxial structure of FIG. 1. Refer to FIG. 1 and FIG. 2, a semiconductor device 100 includes a substrate 110, a plurality of epitaxial structures 120 and a plurality of gate structures 130. The substrate 110 includes a plurality of recesses 111,111a and a plurality of convex portions 112. Each of the convex portions 112 is located between the two adjacent recesses 111, 111a. The epitaxial structures 120 are located in the recesses 111,111a of the substrate respectively. Each of the epitaxial structures 120 includes a first transition layer 122, a second transition layer 124 and an epitaxial layer 126. The first transition layer 122 is located on a bottom surface and a sidewall of one of the recesses 111, 111a. The second transition layer 124 is disposed along the first transition layer 122, in which a material of the second transition layer 124 is different from a material of the first transition layer 122. The epitaxial layer 126 is located on the second transition layer 124 and fills one of the recesses 111, 111a. The gate structures 130 are located on the convex portions 112 of the substrate respectively.

In some embodiments, the material of the first transition layer 122 includes pseudomorphic silicon germanium crystal. The material of the second transition layer 124 includes silicon nucleation crystal. The material of the epitaxial layer 126 includes silicon germanium. As a result of such a structure, it can release the internal energy accumulated due to the big difference of the lattice constant of the substrate 110 and the lattice constant of the epitaxial layer 126. The local equilibrium can be preserved through releasing the internal energy by the first transition layer 122 and the second transition layer 124.

Since the epitaxial structure 120 has the first transition layer 122 and the second transition layer 124 between the epitaxial layer 126 and the substrate 110, such that it won't accumulate too much internal energy between the epitaxial layer 126 located on the second transition layer 124 and the substrate 110 located below the first transition layer 122 due to the big difference of the lattice constant of the substrate 110 and the lattice constant of the epitaxial layer 126. The first transition layer 122 and the second transition layer 124 can help release the internal energy to prevent the rupture of the lattice due to the release of internal energy and causes the situation of non-alignment of the lattice. At the same time, it prevents a misfit dislocation defect, such that the compressive strain exerted to the current channel by the source/drain region formed by epitaxial structure 120 can be preserved, and thus preserves the charge mobility of the current channel and the magnitude of the saturation current, so that the transistor can operate without the possibility of the decrease of the saturation current.

In addition, in the present embodiment, each of the epitaxial structures 120 has a convex portion 121, and the convex portion 121 protrudes to one of the convex portions 112 of the substrate 110. Each of the sidewall of the recesses 111,111a of the substrate 110 has a concave portion 113, and the sidewall contacts the first transition layer 122. The concave portions 113 of the sidewalls of the recesses 111,111a couples with the convex portions 121 of the epitaxial structures 120 respectively. As a result of such a design, the convex portion 121 of the epitaxial structures 120 can exert a compressive strain to the convex portions 112 of the substrate 110, which increase the charge mobility of the current channel in the convex portions 112 of the substrate 110, and thus increase the magnitude of the saturation current.

Refer to FIG. 1, the semiconductor device 100 further includes a shallow trench isolation (STI) 140 located in the substrate 110. One of the epitaxial structures 120a located in the recess 111a has a sidewall 123 abuts against the STI 140, and the sidewall 123 abuts against the STI 140 has no convex portion. A sidewall 142 of the STI 140 faces the sidewall 123 of the epitaxial structure 120a abuts against the STI and contacts each other. The sidewall 142 of the STI 140 has no concave portion.

It is to be noted that the connection relationships, the materials, and the advantages of the elements described above will not be repeated in the following description. In the following description, a manufacturing method of the semiconductor device is described.

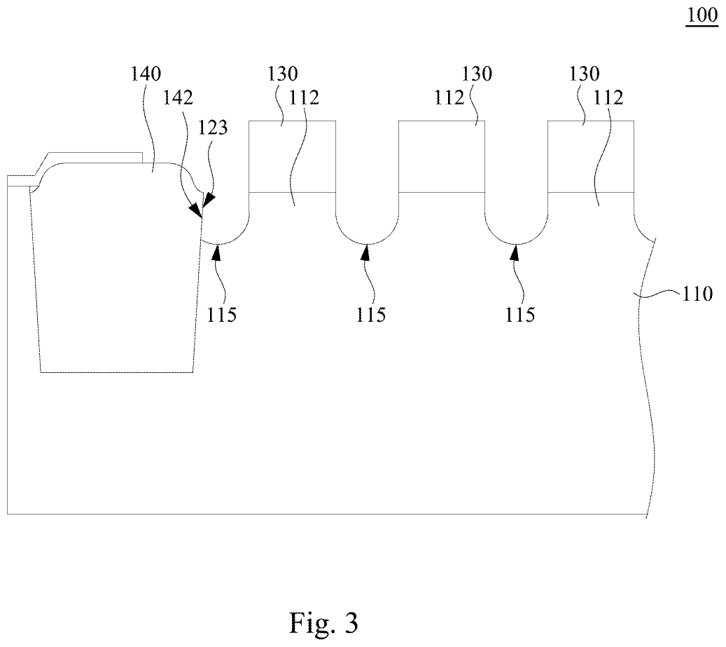

FIG. 3 to FIG. 8 are cross-sectional views at intermediate steps of a manufacturing method of a semiconductor device according to one embodiment of the present disclosure. Refer to FIG. 3, a manufacturing method of a semiconductor device includes forming a shallow trench isolation (STI) 140, a plurality of gate structures 130 and a plurality of transition recesses 115 on a substrate 110, in which the transition recesses 115 are located between the gate structures 130 and between the STI 140 and the gate structure 130 closest to the STI 140. Forming the transition recesses 115 is performed by dry etching. The plasma free radical used for dry etching includes hydrobromic acid (HBr), chlorine (Cl₂) and hydrogen gas (H₂), but not limited to these.

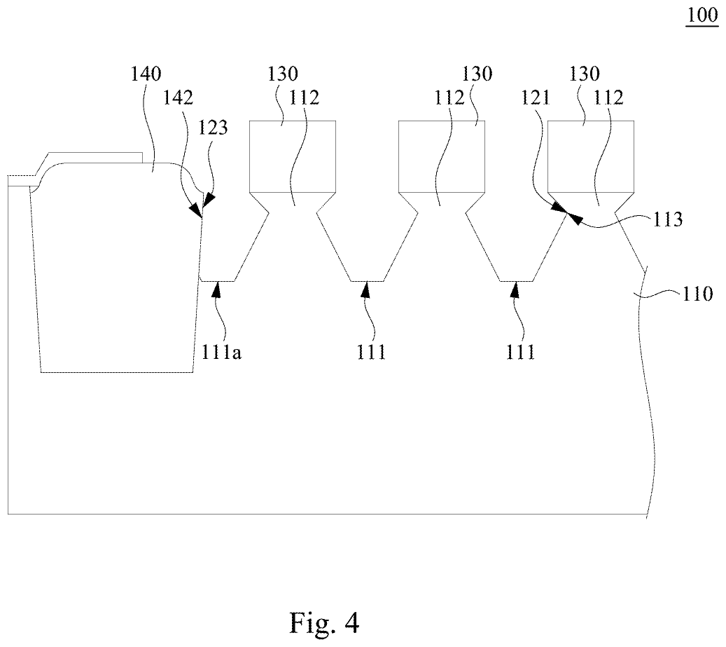

Refer to FIG. 4, after the said step, etching the transition recesses 115 to form a plurality of recesses 111,111a, in which a sidewall of each of the recesses 111,111a has a concave portion 113. Etching the transition recesses 115 of FIG. 3 to form the recesses 111,111a is performed by wet etching. The solution for wet etching can be, as an example, tetramethylammonium hydroxide (TMAH), but not limited to this.

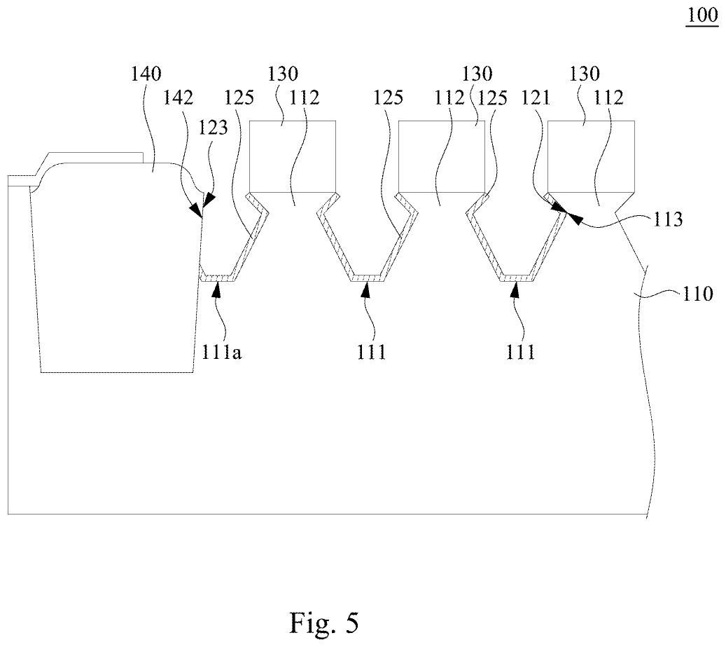

Refer to FIG. 5, thereafter, depositing a silicon atom layer 125 on the bottom surface and the sidewall of the recesses 111,111a. At this step, the lattice constant of the silicon atom layer 125 and the lattice constant of the substrate 110 below is the same, and will be used as the basis to form the pseudomorphic crystal of the first transition layer 122. The method to deposit the silicon atom layer 125 can be atomic layer deposition (ALD) or chemical vapor deposition (CVD), or the combination thereof, or other method to deposit the silicon atom layer 125.

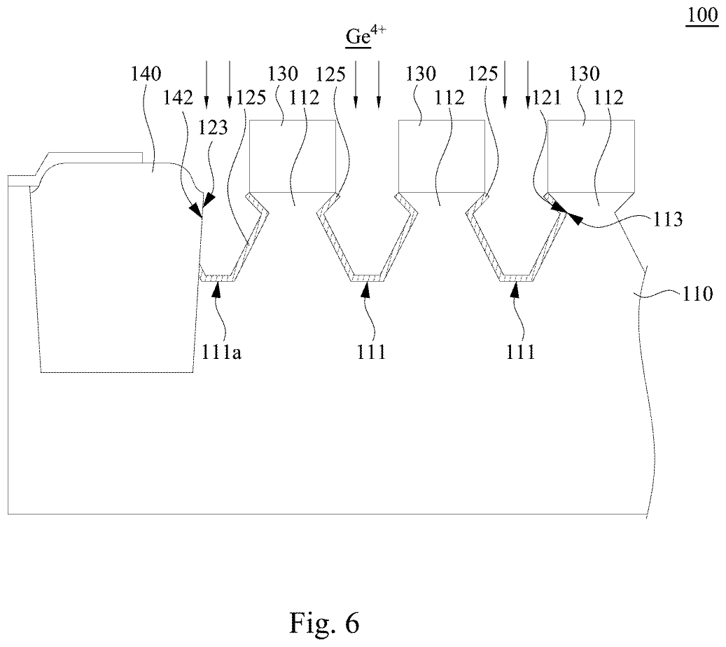

Refer to FIG. 6, after depositing the silicon atom layer 125, implanting a germanium ion (Ge⁴⁺) to the silicon atom layer 125. The germanium ion of FIG. 6 has a valence number of 4, but germanium ions with other number of valence electrons (such as Ge³⁺ with a valence number of 3, Ge²⁺ with a valence number of 2) can also be used in ion implantation. Ion implantation is a process of forming pseudomorphic crystal. By implanting germanium ion to the silicon atom layer 125, the lattice in the silicon atom layer 125 will be disorganized, and implants germanium ion to the silicon atoms.

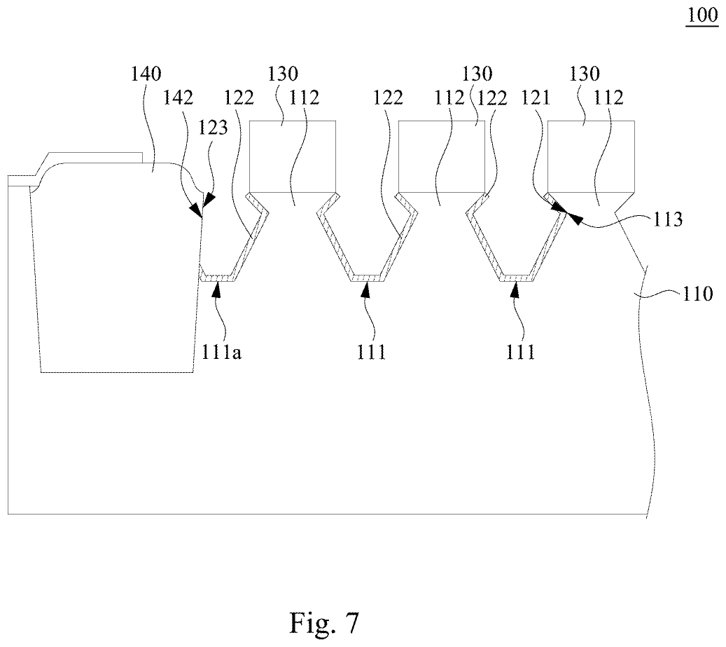

Refer to FIG. 7, thereafter, performing a thermal anneal to the silicon atom layer 125 to form the first transition layer 122. After implanting germanium to the silicon atom layer 125, give it a high temperature to let the silicon and the germanium inside form a pseudomorphic silicon germanium crystal that has a lattice constant closer to the substrate 110 below. The purpose of the usage of the pseudomorphic crystal is to replace a portion of the silicon atoms of the silicon atom layer 125 with germanium. Such a method can form the first transition layer 122, which is a layer of silicon germanium crystal. Since, however, the formation of the first transition layer 122 is depositing the silicon atom layer 125 and implanting a germanium ion, the lattice constant of this transition layer will be closer to the lattice constant of the substrate than the lattice constant of a general silicon germanium epitaxy.

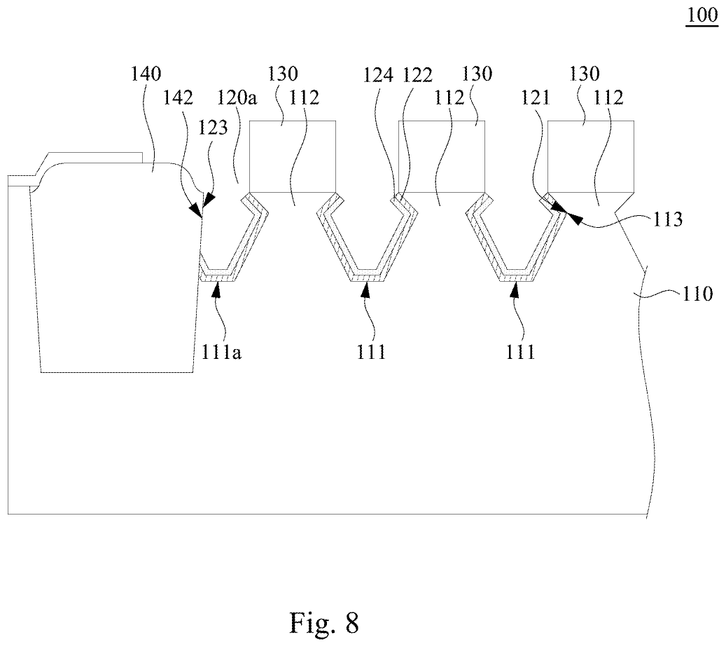

Refer to FIG. 8, thereafter, forming a second transition layer 124 along the first transition layer 122, in which the material of the first transition layer 122 is different from the material of the second transition layer 122. Forming the second transition layer 124 along the first transition layer 122 includes depositing a silicon atom layer in the recesses 111. Since the silicon atoms are deposited on the pseudomorphic crystal, the lattice constant of the silicon nucleation layer of the second transition layer 124 will be slightly different to the lattice constant of the substrate 110 below, which will be closer to the lattice constant of silicon germanium epitaxy, and thus act as a transition layer. The method to deposit the silicon atom layer can be ALD or CVD, or the combination thereof, or other method to deposit the silicon atom layer.

Refer to FIG. 1 and FIG. 8, thereafter, growing an epitaxial layer 126 on the second transition layer 124. The epitaxial layer 126 is silicon germanium epitaxy. After this step, the semiconductor device 100 of FIG. 1 is manufactured. Since there are the first transition layer 122 and the second transition layer 124 in between, there won't be a sudden large change in lattice constant between the epitaxial layer 126 and the substrate 110, which results in a massive internal energy between the two layers. The function of the first transition layer 122 and the second transition layer 124 is to let the change of lattice constant became gradually layer by layer, thus release the stress energy between the epitaxial layer 126 and the substrate 110, which reduces the breakdown of lattice causes by the sudden change of the lattice constant, which causes the misfit dislocation defect.

In summary, since the epitaxial structure has the first transition layer 122 and the second transition layer 124 between the epitaxial layer 126 and the substrate 110, such that it won't accumulate too much internal energy between the epitaxial layer 126 located on the second transition layer 124 and the substrate 110 below the first transition layer 122 due to the big difference of the lattice constant of the substrate 110 and the lattice constant of the epitaxial layer 126. Since the first transition layer 122 is a pseudomorphic silicon germanium crystal layer formed by replacing a portion of the silicon atoms of the silicon atom layer 125 with germanium, the lattice constant of the first transition layer 122 is closer to the lattice constant of the substrate 110 compare to the general silicon germanium epitaxy. Also, since the second transition layer 124 is deposited on the pseudomorphic crystal, the lattice constant of the second transition layer 124 will be closer to the epitaxial layer 126 compare to the lattice constant of the substrate 110. Therefore, the first transition layer 122 and the second transition layer 124 let the change of lattice constant became gradually layer by layer, help release the internal energy caused by large difference of the lattice constant and prevent the rupture of the lattice due to the release of internal energy and causes the situation of non-alignment of the lattice, which prevents misfit dislocation defect, such that the compressive strain exerted to the current channel by the source/drain region formed by epitaxial structure 120 can be preserved, and thus preserves the charge mobility of the current channel and the magnitude of the saturation current, so that the transistor can operate without the possibility of the decrease of the saturation current.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a substrate comprises a plurality of recesses and a plurality of convex portions, each of the convex portions is located between the two adjacent recesses;
a plurality of epitaxial structures located in the recesses of the substrate respectively, each of the epitaxial structures comprising:
a first transition layer located on a bottom surface and a sidewall of one of the recesses;
a second transition layer disposed along the first transition layer, in which a material of the second transition layer is different from a material of the first transition layer; and
an epitaxial layer located on the second transition layer and fills one of the recesses; and
a plurality of gate structures located on the convex portions of the substrate respectively.

2. The semiconductor device of claim 1, wherein each of the epitaxial structures has a convex portion, and the convex portion protrudes to one of the convex portions of the substrate.

3. The semiconductor device of claim 2, wherein each of the sidewall of the recesses of the substrate has a concave portion, and the sidewall contacts the first transition layer.

4. The semiconductor device of claim 3, wherein the concave portions of the sidewalls of the recesses couples with the convex portions of the epitaxial structures respectively.

5. The semiconductor device of claim 1, wherein the semiconductor device further comprising:
a shallow trench isolation (STI) located in the substrate, wherein one of the epitaxial structures has a sidewall abuts against the STI, and the sidewall abuts against the STI has no convex portion.

6. The semiconductor device of claim 5, wherein a sidewall of the STI faces the sidewall abuts against the STI.

7. The semiconductor device of claim 6, wherein the sidewall of the STI has no concave portion.

8. The semiconductor device of claim 1, wherein a material of the first transition layer comprises pseudomorphic silicon germanium crystal.

9. The semiconductor device of claim 1, wherein a material of the second transition layer comprises silicon nucleation crystal.

10. The semiconductor device of claim 1, wherein a material of the epitaxial layer comprises silicon germanium.

11. A manufacturing method of a semiconductor device, comprising:
forming a shallow trench isolation (STI), a plurality of gate structures and a plurality of transition recesses on a substrate, wherein the transition recesses are located between the gate structures and between the STI and the gate structure closest to the STI;
etching the transition recesses to form a plurality of recesses, wherein a sidewall of each of the recesses has a concave portion;
forming a first transition layer on bottom surfaces and the sidewalls of the recesses;
forming a second transition layer along the first transition layer, wherein a material of the first transition layer is different from a material of the second transition layer; and
growing an epitaxial layer on the second transition layer.

12. The manufacturing method of the semiconductor device of claim 11, wherein forming the first transition layer on the bottom surfaces and the sidewalls of the recesses comprises:
depositing a silicon atom layer in the recesses;
implanting a germanium ion to the silicon atom layer; and
performing a thermal anneal to the silicon atom layer to form the first transition layer.

13. The manufacturing method of the semiconductor device of claim 11, wherein forming the second transition layer along the first transition layer comprising:
depositing a silicon atom layer in the recesses.

14. The manufacturing method of the semiconductor device of claim 13, wherein forming the second transition layer along the first transition layer is performed by atomic layer deposition (ALD) or chemical vapor deposition (CVD).

15. The manufacturing method of the semiconductor device of claim 11, wherein forming the transition recesses is performed by dry etching, and etching the transition recesses to form the recesses is performed by wet etching.
